(19) United States
(12) Patent Application Publication
(10) Pub. No.: US 2024/0040754 A1
(43) Pub. Date: Feb. 1, 2024

(54) POWER SEMICONDUCTOR MODULES AND METHOD FOR THEIR ASSEMBLING

(71) Applicants: Nexperia Technology (Shanghai) Ltd., Shanghai (CN); NEXPERIA B.V., Nijmegen (NL)

(72) Inventors: Qiuxiao Qian, Shanghai (CN); Chunlin Zhu, Shanghai (CN); Ke Jiang, Shanghai (CN)

(73) Assignees: Nexperia Technology (Shanghai) Ltd., Shanghai (CN); NEXPERIA B.V., Nijmegen (NL)

(21) Appl. No.: 18/324,731

(22) Filed: May 26, 2023

(30) Foreign Application Priority Data
May 30, 2022 (CN) 202210600902.3

(51) Int. Cl. H05K 7/20

(52) U.S. Cl. CPC H05K 7/209; H05K 7/20418

(57) ABSTRACT

The disclosure provides power semiconductor modules and their assembling methods. The module includes a heat-dissipation contact area, a housing and a press-on element. One of the housing and the press-on element includes a rail portion, while the other includes a rail cooperating portion. The housing and the press-on element respectively includes a first limiting portion and a first limiting cooperating portion. The rail cooperating portion can be inserted into the rail portion and slides on the rail portion in the direction toward or away from the plane where the heat-dissipation contact area is located, so that the press-on element could move from the separation position to the mounted position connected with the housing. The rail portion can cooperate with the rail cooperating portion to prevent the press-on element from moving relative to the housing in the direction parallel to the plane where the heat-dissipation contact area is located.

### CROSS-REFERENCE TO RELATED APPLICATIONS

This application claims the benefit under 35 U.S.C. § 119(a) of Chinese Application No. 202210600902.3 filed May 30, 2022, the contents of which are incorporated by reference herein in their entirety.

### BACKGROUND

### 1. Field of the Disclosure

The present disclosure relates to power semiconductor modules, and methods for assembling the power semiconductor module.

### 2. Description of the Related Art

During operation, power semiconductor chips generate heat, which needs to be dissipated to maintain the proper functions of the power semiconductor chips. Furthermore, power semiconductor chips are often integrated by using a power semiconductor module with a housing. Compared with discrete chips or devices, power semiconductor modules are easier to be used, but have higher heat dissipation requirements.

A common manner of heat dissipation for a power semiconductor module is to make a heat-dissipation contact area coated with heat conductive silicone grease at the bottom of the module directly contact with a heat sink element (comprising a cooling element) to dissipate heat generated by a semiconductor chip and the like in the power semiconductor module to the environment through the heat conductive silicone grease and the heat sink element. However, the size of the power semiconductor module is generally big, and portions near the edges of the power semiconductor module are gradually warped as heat is generated. On the other hand, since the heat conductive silicone grease has fluidity, when the power semiconductor module is attached to the heat sink element, the heat conductive silicone grease between the power semiconductor module and the heat sink element is squeezed to fill up a gap between the bottom of the power semiconductor module and the heat sink element. Therefore, the larger the warpage is, the larger the local gap between the heat-dissipation contact area and the heat sink element is, and hence the thicker the heat conductive silicone grease in local regions is. Since the heat conductivity of the heat conductive silicone grease is lower than that of the heat sink element, and the heat dissipation capability of the heat conductive silicone grease is also inferior to that of the heat sink element, excessive warpage is likely to hinder the heat dissipation efficiency of the power semiconductor module.

In order to solve the warpage problem of the power semiconductor module during use, the prior art has the following two designs.

One design in the prior art is disclosed in, for example, U.S. D0922329S, in which, as shown in FIG. 1, two flanges 10a with through holes are integrally formed at lower portions on both sides of a housing 1a of a power semiconductor module. Screw holes are correspondingly formed in a heat sink element, and the housing is fixed to the heat sink element with screws (or bolts) passing through the through holes. In this design, the contact between the power semiconductor module and the heat sink element is a rigid contact, which is not only disadvantageous to reduce the gap between the heat-dissipation contact area and the heat sink element, but also prone to aging at the stressed positions, which is disadvantageous to long-term use. Furthermore, the design shown in FIG. 1 is less reliable in a vibrating environment.

Another design in the prior art is disclosed in, for example, U.S. Pat. No. 7,477,518B2, in which, as shown in FIG. 2, a plastic housing 2a molded with press-on elements is applied. When manufacturing the power semiconductor module, one end 21a of the press-on element 20a is inserted into a plastic injection molding die for making the housing, thereby embedding the press-on element into the side wall of the housing while injection molding the housing. The other end 22a of the press-on element is provided with a through hole, and the housing 2a is fixed to the heat sink element with a screw (or bolt) passing through the through hole similarly. Although the design shown in FIG. 2 enables flexible contact between the press-on element and the heat sink element, which is beneficial for long-term use, it leads to a complicated manufacturing process of the housing and a high manufacturing cost.

Furthermore, both designs shown in FIGS. 1 and 2 result in the power semiconductor module being applicable only to glue-filled plastic modules, but not to plastic encapsulated modules. Specifically, the housing of the plastic module is typically manufactured separately. During packaging, the plastic housing and the substrate (such as a copper-clad ceramic substrate or a copper substrate) are bonded by glue, and then the silicone gel is poured into the plastic housing. In contrast, for plastic encapsulated modules, typically, a thermosetting material such as an Epoxy Molding Compound (EMC) is extruded into a mold cavity and embeds the semiconductor chips therein. This method is not suitable for manufacturing the portion of the housing to which the heat sink element is fixed (e.g., the above-described flange 10a and the pressing member 20a). The two designs shown in FIGS. 1 and 2 are not suitable for plastic encapsulated modules. In addition, the size of the power semiconductor module thus produced is big, which is not advantageous to the packaging process and the baling and transporting process.

Therefore, it is desirable to provide an improved power semiconductor module that can solve the above technical problems.

### SUMMARY

The present disclosure provides a power semiconductor module and a method for assembling the power semiconductor module.

Specifically, the present disclosure provides a power semiconductor module, including: a heat-dissipation contact area configured for thermal connection with a heat sink element; a housing; and a press-on element manufactured separately from the housing. One of the housing and the press-on element includes a rail portion, and the other includes a rail cooperating portion. One of the housing and the press-on element includes a first limiting portion, and the other includes a first limiting cooperating portion. The rail cooperating portion is capable of being inserted into the rail portion and sliding in the rail portion in a direction toward or away from a plane where the heat-dissipation contact area is located, such that the press-on element is capable of moving from a separation position in which the press-on element is separated from the housing to a mounted position in which the press-on element is connected to the housing. The rail portion is capable of cooperating with the rail cooperating portion to prevent the press-on element from moving relative to the housing in a direction parallel to the plane where the heat-dissipation contact area is located. The first limiting portion is capable of cooperating with the first limiting cooperating portion to prevent the press-on element from moving relative to the housing in a direction toward the plane where the heat-dissipation contact area is located when the press-on element is in the mounted position. The press-on element is configured to press the heat-dissipation contact area against the heat sink element when the press-on element is in the mounted position and the press-on element is mounted to the heat sink element.

Optionally, the rail portion is located on the housing. The press-on element further includes a main body portion. The rail cooperating portion is configured to project laterally from the main body portion and extend in a direction in which the rail portion extends.

Optionally, the press-on element is configured to be adapted to move from an entry position on a side of the housing close to the heat-dissipation contact area to the mounted position in a direction away from the plane where the heat-dissipation contact area is located. The first limiting portion is configured as a protrusion on the housing. The protrusion has a non-returning surface facing away from the plane where the heat-dissipation contact area is located, and a guiding surface extending obliquely from a tip end of the non-returning surface toward the heat-dissipation contact area. The guiding surface is used for guiding the main body portion during the movement of the press-on element from the entry position to the mounted position. The first limiting portion is configured as a window on the main body portion. When the press-on element is in the mounted position, the protrusion passes through the window, and the non-returning surface of the protrusion is capable of cooperating with a surface of the window facing the plane where the heat-dissipation contact area is located to prevent the press-on element from moving relative to the housing in a direction toward the plane where the heat-dissipation contact area is located.

Optionally, the press-on element is configured to be adapted to move from an entry position on a side of the housing close to the heat-dissipation contact area to the mounted position in a direction away from the plane where the heat-dissipation contact area is located. The first limiting portion is configured as a recess on the housing. The first limiting portion is configured as an elastic element on the main body portion. When the press-on element is in the mounted position, the elastic element is capable of cooperating with the recess to prevent the press-on element from moving relative to the housing in a direction toward the plane where the heat-dissipation contact area is located.

Optionally, the elastic element is an elastic sheet that is bent and/or tilted toward the housing. When the press-on element is in the mounted position, a tip end of the elastic sheet abuts against a surface of the recess facing away from the plane where the heat-dissipation contact area is located.

Optionally, the press-on element is configured to be adapted to move from an entry position on a side of the housing away from the heat-dissipation contact area to the mounted position in a direction toward the plane where the heat-dissipation contact area is located. The first limiting portion is a first stop surface on the housing. When the press-on element is in the mounted position, the first limiting cooperating portion is capable of cooperating with the first stop surface to prevent the press-on element from moving relative to the housing in a direction toward the plane where the heat-dissipation contact area is located.

Optionally, the rail portion is located on the housing. The first stop surface is located in a portion of the rail portion close to the heat-dissipation contact area. The rail cooperating portion is located on the press-on element. When the press-on element is in the mounted position, the first limiting cooperating portion is located at an end of the rail cooperating portion. The first limiting cooperating portion is capable of cooperating with the first stop surface to prevent the press-on element from moving relative to the housing in a direction toward the plane where the heat-dissipation contact area is located.

Optionally, the press-on element is made of a material having elasticity.

Optionally, the housing and the press-on element include a second limiting portion and a second limiting cooperating portion, respectively. When the press-on element is in the mounted position, the second limiting portion is capable of cooperating with the second limiting cooperating portion to prevent the press-on element from moving relative to the housing in a direction away from the plane where the heat-dissipation contact area is located.

Optionally, the housing and the press-on element include a second limiting portion and a second limiting cooperating portion, respectively. The second limiting portion is configured as a second stop surface facing the plane where the heat dissipation contact area is located. The second limiting cooperating portion is located at an end of the main body portion or the rail cooperating portion. When the press-on element is in the mounted position, the second stop surface is capable of cooperating with the second limiting cooperating portion to prevent the press-on element from moving relative to the housing in a direction away from the plane where the heat-dissipation contact area is located.

Optionally, the second limiting portion is configured as a protrusion on the housing. The protrusion has a non-returning surface facing away from the plane where the heat-dissipation contact area is located, and a guiding surface extending obliquely away from the plane where the heat-dissipation contact area is located from a tip end of the non-returning surface. The guiding surface is used for guiding the main body portion during the movement of the press-on element from the entry position to the mounted position. The second limiting portion is configured as a window on the main body portion. When the press-on element is in the mounted position, the protrusion passes through the window, and the non-returning surface of the protrusion is capable of cooperating with a surface of the window away from the plane where the heat-dissipation contact area is located to prevent the press-on element from moving relative to the housing in a direction away from the plane where the heat-dissipation contact area is located.

Optionally, a self-locking structure is provided on the non-returning surface. The self-locking structure is configured to be capable of cooperating with the window to prevent the press-on element in the mounted position from moving outward in a direction away from the housing.

Optionally, the numbers of the rail portions and the rail cooperating portions are two, respectively. The spaces in the two rail portions for accommodating the corresponding rail cooperating portions are opened toward each other.

Optionally, the number of the press-on elements is at least two. In the mounted position, two of the press-on elements are mounted on opposite sides of the housing, respectively.

Optionally, the press-on element is adapted to be detachably mounted to the housing.

Optionally, the first limiting portion is integrally formed on the housing.

Optionally, the first limiting cooperating portion is integrally formed on the press-on element.

Optionally, the rail portion is integrally formed on the housing or the press-on element.

Optionally, the rail cooperating portion is integrally formed on the housing or the press-on element.

Optionally, the housing is made of plastic.

Optionally, the press-on element is made of metal.

The present disclosure also provides method for assembling the above-mentioned power semiconductor module to the heat sink element, the method including: placing the press-on element at an entry position on the housing, sliding the rail cooperating portion in the rail portion to move the press-on element from the entry position to the mounted position; and mounting the press-on element on the heat sink element such that the heat-dissipation contact area abuts against the heat sink element tightly.

Optionally, before mounting the press-on element to the heat sink element, the method further includes: applying a heat conductive silicone grease on the heat-dissipation contact area and/or the surface of the heat sink element.

The power semiconductor module and the method for assembling the same provided by the present disclosure have the following advantages: making the power semiconductor modules less difficult to product, widely applicable, have long service life and small size, easy to package, bale and transport, capable of inhibiting the occurrence of warping in long-term use and keeping stable contact between the heat-dissipation contact area and the heat sink element.

### BRIEF DESCRIPTION OF THE DRAWINGS

FIG. 1 is a design of a housing and a hold-down press-on member element of a power semiconductor module in the prior art;

FIG. 2 is another design of a power semiconductor module including a housing and a press-on element in the prior art;

FIG. 3 is a schematic cross-sectional view of a power semiconductor module with a press-on element in a mounted position according to a first embodiment of the present disclosure;

FIG. 4 is a top perspective view of the power semiconductor module with the press-on element in the mounted position according to the first embodiment of the present disclosure;

FIG. 5 is a top view of the power semiconductor module of FIG. 4;

FIG. 6 is a top perspective view of the housing and the press-on element of the power semiconductor module with the press-on element in a separation position according to the first embodiment of the present disclosure;

FIG. 7 is a schematic view showing the mounting process of the press-on element according to the first embodiment of the present disclosure;

FIG. 8 is a schematic cross-sectional view of the power semiconductor module mounted to the heat sink element according to the first embodiment of the present disclosure;

FIG. 9 is a perspective view of a housing of a power semiconductor module with a press-on element in the mounted position according to a second embodiment of the present disclosure;

FIG. 10 is a perspective view of the housing of the power semiconductor module with the press-on element in the separation position according to the second embodiment of the present disclosure;

FIG. 11 is a side view of the press-on element of the power semiconductor module according to the second embodiment of the present disclosure;

FIG. 12 is a perspective view of a housing of a power semiconductor module with a press-on element in the mounted position according to a third embodiment of the present disclosure;

FIG. 13 is a perspective view of the housing of the power semiconductor module with the press-on element in the separation position according to the third embodiment of the present disclosure;

FIG. 14 is a perspective view of a housing and a press-on element of a power semiconductor module according to a fourth embodiment of the present disclosure; and

FIG. 15 is a partially enlarged view of a housing of a power semiconductor module according to a fifth embodiment of the present disclosure.

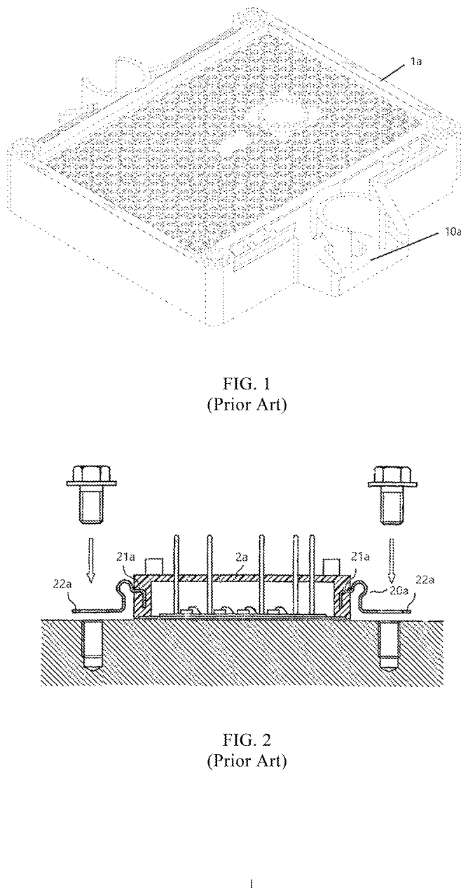

### DETAILED DESCRIPTION

The present disclosure will now be described, by way of examples, with reference to the accompanying drawings. The following description discloses or illustrates various objects, features and aspects of the present disclosure. It will be understood by those skilled in the art that the following discussion is intended to describe exemplary embodiments only, and is not intended as limiting the broader aspects of the present disclosure, which are embodied in the exemplary constructions. Table 1 is a list of components in the drawings along with corresponding reference numerals, wherein the same or similar reference numerals to each other denote the same or similar components to each other in the drawings. Thus, once a component is defined in one embodiment, further definition and explanation of thereof may be omitted in other embodiments.

TABLE 1

| Reference numeral | Component |
|---|---|
| 1 | power semiconductor module |
| 10:110: 210: 310 | housing |
| 11: 111: 211: 311 | rail portion |
| 12: 215: 312 | protrusion |
| 13: 213 | non-returning surface |
| 14: 214 | guiding surface |
| 15 | second stop surface |
| 16 | projection where the second stop surface 15 |
| | is located |
| 17 | self-locking structure |
| 20: 120: 220: 320 | press-on element |
| 21: 121: 221: 321 | rail cooperating portion |
| 22: 225: 322 | window |
| 23: 123: 223: 323 | main body portion |
| 25 | upper end portion of rail cooperating portion 21 |
| 125 | upper end portion of rail cooperating portion 121 |
| 30 | heat-dissipation contact area |
| 41 | power semiconductor substrate |
| 42 | power semiconductor chip |
| 43 | terminal pain |
| 44 | screw |
| 112 | recess |
| 122 | elastic element |
| 212 | first stop surface |
| 222 | lower end portion of rail cooperating portion 221 |
| D | heat sink element |

In the description of the present disclosure, it should be noted that the terms “top”, “bottom”, “upper”, “lower”, “left”, “right”, “inner”, “outer”, and the like indicate orientations or positional relations based on orientations or positional relations shown in the drawings or orientations or positional relations that a product is conventionally arranged when in use, and are merely used for convenience of description and simplification of description, but do not indicate or imply that the device or element referred to must have a specific orientation, be constructed and operated in a specific orientation. Therefore, they should not be construed as limiting the present disclosure. Of course, when the power semiconductor module is mounted in a circuit, the positional relationship between the components should be based on the actual orientation.

Furthermore, in the description of the present disclosure, unless otherwise specified, expressions in the singular form may include concepts in the plural.

Furthermore, the terms “first,” “second,” and the like are used solely to distinguish one element from another, but should not be understood as indicating or implying relative importance or order.

In addition, it should be noted that the features in the embodiments of the present disclosure could be arbitrarily combined with each other in case of no conflict.

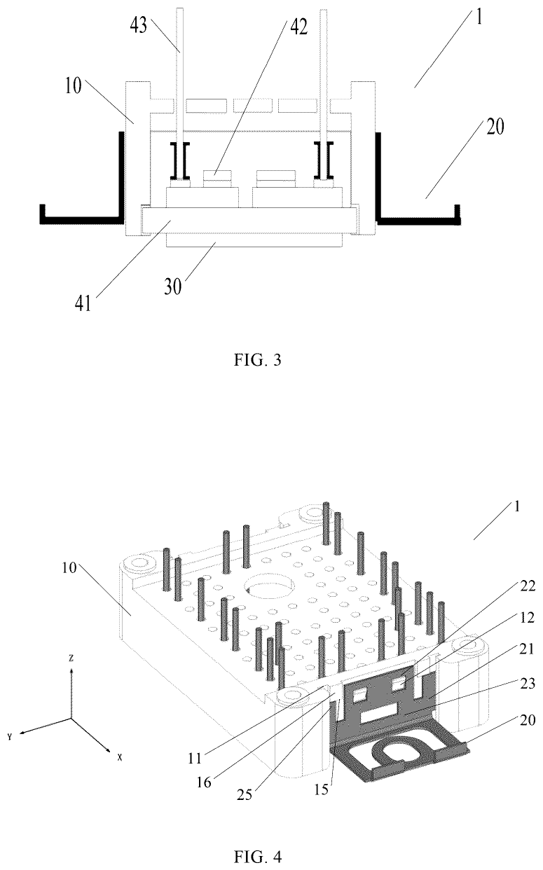

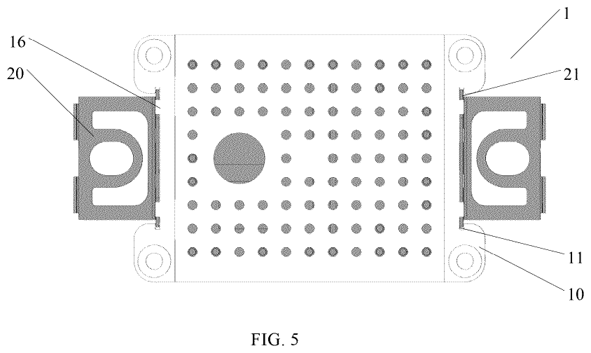

FIGS. 3 to 14 show power semiconductor modules (1) according to different embodiments of the present disclosure. The power semiconductor module (1) includes a housing (10; 110; 210; 310), a press-on element (20; 120; 220; 320) and a heat-dissipation contact area 30. The heat-dissipation contact area 30 is configured for thermal connection with a heat sink element D. One of the housing element (10; 110; 210; 310) and press-on element (20; 120; 220; 320) includes a rail portion (11; 111; 211; 311), and the other includes a rail cooperating portion (21; 121; 221; 321). As an example, in FIGS. 4 to 13, the rail portions (11; 111; 211) are all on the housing (10; 110; 210) and the rail cooperating portions (21; 121; 221) are all on the press-on element (20; 120; 220).

The rail cooperating portion (21; 121; 221; 321) is capable of being inserted into the rail portion (11; 111; 211; 311) and sliding in the rail portion (11; 111; 211; 311) in a direction toward or away from the plane where the heat-dissipation contact area 30 is located (i.e. in the up-down direction), so that press-on element (20; 120; 220; 320) is capable of moving from a separation position, in which the press-on element is separated from the housing (10; 110; 210; 310), to a mounted position, in which the press-on element is connected to housing (10; 110; 210; 310). The rail portion (11; 111; 211; 311) is capable of cooperating with the rail cooperating portion (21; 121; 221; 321) to prevent the press-on element (20; 120; 220; 320) from moving relative to the housing (10; 110; 210; 310) in a direction parallel to the plane in which the heat-dissipation contact area lies, i.e. in a lateral plane. In other words, the cooperation of the rail portion (11; 111; 211; 311) and the rail cooperating portion (21; 121; 221; 321) only prevents movement in the lateral plane, but allows movement in the up-down direction.

The housing (10; 110; 210; 310) and the press-on element (20; 120; 220; 320) respectively include a first limiting portion (12; 112; 212; 312) and a first limiting cooperating portion (22; 122; 222; 322). One of the housing (10; 110; 210; 310) and the press-on element (20; 120; 220; 320) includes the first limiting portion (12; 112; 212; 312), and the other includes the first limiting cooperating portion (22; 122; 222; 322). For example, in FIGS. 4-14, the first limiting portions (12; 112; 212; 312) are all on the housing (10; 110; 210; 310), and the first limiting cooperating portions (22; 122; 222; 322) are all on the press-on element (20; 120; 220; 320). When the press-on element (20; 120; 220; 320) is in the mounted position, the first limiting portion (12; 112; 212; 312) could cooperate with the first limiting cooperating portion (22; 122; 222; 322) to prevent the press-on element (20; 120; 220; 320) from moving relative to the housing (10; 110; 210; 310) in the direction toward the plane where the heat-dissipation contact area 30 is located, i.e. moving downward in FIGS. 3 to 4 and 6 to 14. In other words, the first limiting portion (12; 112; 212; 312) and the first limiting cooperating portion (22; 122; 222; 322) are used for preventing the press-on element from moving downward relative to the housing after the press-on element (20; 120; 220; 320) reaches the mounted position. That is, the first limiting portion and the first limiting cooperating portion do not limit the relative movement between the press-on element and the housing during the movement of the press-on element.

The press-on element (20; 120; 220; 320) is configured for pressing the heat-dissipation contact area 30 against heat sink element D when the press-on element is in the mounted position and is mounted to the heat sink element. In other words, when the power semiconductor module (1) is mounted on heat sink element D, the heat sink element D is respectively in contact with the heat-dissipation contact area 30 and fixed to the press-on element (20; 120; 220; 320), so that the press-on element (20; 120; 220; 320) is prevented from moving upward relative to the housing.

Through the above design, the power semiconductor module of the present disclosure has the following advantages: low production difficulty, wide application range, long service life, small size, convenience for packaging, baling and transporting, capability of inhibiting the occurrence of warping in long-term use and keeping stable contact between the heat-dissipation contact area and the heat sink element.

As shown in FIGS. 4-13, in various embodiments of the present disclosure, the rail portion (11; 111; 211) may be located on housing (10; 110; 210). The press-on element (20; 120; 220) further includes a main body portion (23; 123; 223). The rail cooperating portion (21; 121; 221) is configured to project laterally from the main body portion (23; 123; 223) and extend in a direction in which the rail portion (11; 111; 211) extends. In other words, the rail portion (11; 111; 211) and the rail cooperating portion (21; 121; 221) both extend in the up-down direction. The rail portion (11; 111; 211) is provided on the housing (10; 110; 210) to facilitate the manufacture of the housing (10; 110; 210) and the press-on element (20; 120; 220).

According to embodiments of the present disclosure, as shown in FIGS. 4 to 11, the press-on element (20; 120) may be configured to be adapted to move from an entry position on a side of the housing (10; 110) close to the heat-dissipation contact area 30 (i.e., the lower side of the housing) to a mounted position in a direction away from the plane where the heat dissipation contact area 30 is located (i.e., upward). Through this structure, the press-on element (20; 120) could be positioned at the mounted position more easily in the mounting process.

According to the embodiments of the present disclosure, the spaces in the two rail portions for accommodating the corresponding rail cooperating portions are opened toward each other.

According to the embodiments of the present disclosure, the number of the press-on elements (20; 120; 220; 320) may be at least two. When in the mounted position, two of the press-on elements (20; 120; 220; 320) are mounted on opposite sides of the housing (10; 110; 210; 310), respectively.

According to the embodiments of the present disclosure, the press-on element (20; 120; 220; 320) may be adapted to be detachably mounted to the housing (10; 110; 210; 310).

According to the embodiments of FIGS. 4 to 14, the first limiting portion (12; 112; 212; 312) may be integrally formed on the housing (10; 110; 210; 310). The first limiting cooperating portion (22; 122; 222; 322) may be integrally formed on the press-on element (20; 120; 220; 320). The rail portion may be integrally formed on the housing (10; 110; 210) or the press-on element 320. The rail cooperating portion may be integrally formed on the housing 310 or the press-on element (20; 120; 220). The housing (10; 110; 210; 310) may be made of plastic. The press-on element (20; 120; 220; 320) may be made of metal (for example, a thin metal sheet) or high polymer material. The metal may be aluminum, magnesium alloy, copper, nickel-plated copper, stainless steel and the like, and the high polymer material may be plastic or high polymer material mixed with filler. The press-on element (20; 120; 220; 320) may be an elastic element.

In the embodiments of the present disclosure, the cooperation between the first limiting portion (12; 112; 212; 312) and the first limiting cooperating portion (22; 122; 222; 322) may be contact cooperation or snap cooperation. Alternatively, the cooperation between the first limiting portion and the first limiting cooperating portion may also be bolt cooperation or screw cooperation.

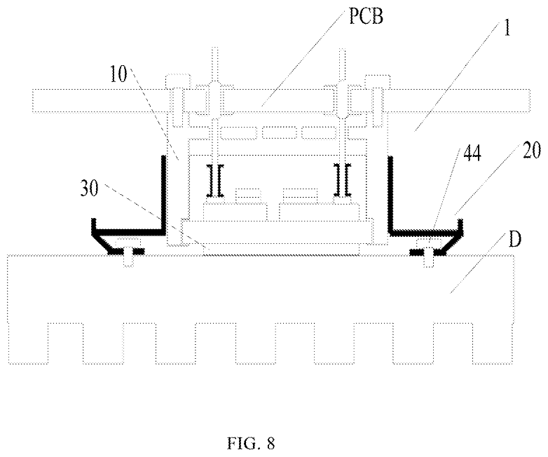

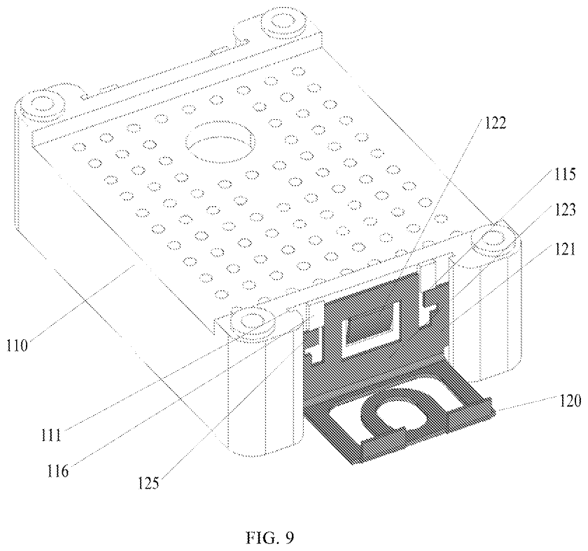

According to embodiments of the present disclosure, a method for assembling the above-mentioned power semiconductor module to a heat sink element includes: placing the press-on element (20; 120; 220; 320) at an entry position on housing (10; 110; 210; 310), sliding the rail cooperating portion in the rail portion to move the press-on element from the entry position to the mounted position; and mounting the press-on element (20; 120; 220; 320) on the heat sink element such that the heat-dissipation contact area abuts against the heat sink element 30 tightly. FIG. 8 shows the power semiconductor module in the mounted state.

Optionally, prior to mounting the press-on element (20; 120; 220; 320) to the heat sink element, the method further includes: the power semiconductor module assembling method further includes: applying a heat conductive silicone grease on the heat-dissipation contact area 30 and/or the surface of the heat sink element.

Hereinafter, various embodiments of the present disclosure will be described in detail.

### First Embodiment

FIGS. 3 to 8 show a power semiconductor module 1 according to the first embodiment of the present disclosure. FIGS. 3 and 8 are schematic cross-sectional views of power semiconductor module 1 in various different states, FIGS. 4 to 6 are views of the power semiconductor module 1 in various different states and seen from various angles, and FIG. 7 is a schematic view of an assembly process of a press-on element 20 of the power semiconductor module 1.

As shown in FIGS. 3 to 5 and 8, the power semiconductor module 1 includes a housing 10, a press-on element 20, and a heat-dissipation contact area 30. Typically, the housing 10 has a substantially rectangular parallelepiped shape, although other shapes (e.g., trapezoidal platforms, trapezoidal columns, hexagonal columns, etc.) are also possible. The heat-dissipation contact area 30 is an area of the power semiconductor module 1 for thermal connection with a heat sink element D (see FIG. 8). In the first embodiment, the heat-dissipation contact area 30 is the bottom surface of a power semiconductor substrate 41, and the power semiconductor substrate 41 is a DBC (direct bonded copper) substrate and is embedded at the bottom of the housing. Power semiconductor chips 42 and the like are provided on the top surface of the power semiconductor substrate 41 and are located within the housing 10, and a plurality of terminal pins 43 extend from the power semiconductor chip 42 or the power semiconductor substrate 41 toward a direction away from the heat-dissipation contact area 30 (i.e., in the Z-axis direction in FIG. 4) and pass out of the housing 10 from through holes at the top of the housing 10. The housing 10 may be filled with silicone gel.

The press-on element 20 is manufactured separately from the housing 10, and the press-on element 20 can be mounted to the housing 10 through a simple assembly process. In the first embodiment, two press-on elements 20 may be mounted on opposite sides of the housing 10, respectively. For clarity, only one of the press-on elements 20 and its associated housing structure will be described.

As shown in FIGS. 4 to 8, the press-on element 20 may include a substantially vertical portion to be cooperated with the housing 10, and a substantially horizontal portion to be cooperated with the heat sink element D, thereby forming a substantial L shape. The substantially vertical portion includes a main body portion 23 and rail cooperating portions 21 on both sides of the main body portion 23. The two rail cooperating portions 21 laterally project from the lower portion of the main body portion 23 opposite to each other, and then extend upwardly, thereby forming a gap between each rail cooperating portion 21 and the main body portion 23. The press-on element 20 may be an elastic element made of a material having certain elasticity (for example, a metal such as aluminum, magnesium alloy, copper, nickel-plated copper, or stainless steel; a polymer material such as plastic; or a polymer material doped with a filler).

Two rail portions 11 corresponding to the two rail cooperating portions 21 are formed in parallel with each other on the side wall of the housing 10. Optionally, the spaces of the two rail portions 11 for accommodating the rail cooperating portions 21 are opened toward each other (for example, cross sections of the two rail portions 11 taken by a plane parallel to the plane where the heat-dissipation contact area 30 is located may have ⊏ shape and ⊐ shape facing each other, respectively).

The rail cooperating portions 21 are slidable within the rail portions 11 in a direction toward or away from the plane where the heat-dissipation contact area 30 is located (i.e., in Z-axis direction or an up-down direction in FIG. 4), so that the press-on element 20 could be moved from a separation position (see FIG. 7), in which the press-on element is separated from the housing 10, to a mounted position (see FIG. 4), in which the press-on element is connected to housing 10. More specifically, the press-on element 20 could be moved vertically upward from an entry position on the lower side of the housing 10 to the mounted position. No matter in the sliding process of the rail cooperating portion 21 or after the press-on element 20 has been in the mounted position, the rail portions 11 are capable of cooperating with the rail cooperating portions 21 to prevent the press-on element 20 from moving relative to the housing 10 in a direction parallel to the plane where the heat-dissipation contact area 30 is located (i.e., in any direction perpendicular to the Z-axis in FIG. 4). In other words, the cooperation between the rail portions 11 and the rail cooperating portions 21 only allows the press-on element 20 to move in the up-down direction. Therefore, once the press-on element 20 has been mounted to the housing 10, the press-on element 20 is prevented by the rail portions 11 from moving in the left-right direction (Y-axis direction in FIG. 4) or the front-back direction (X-axis direction in FIG. 4).

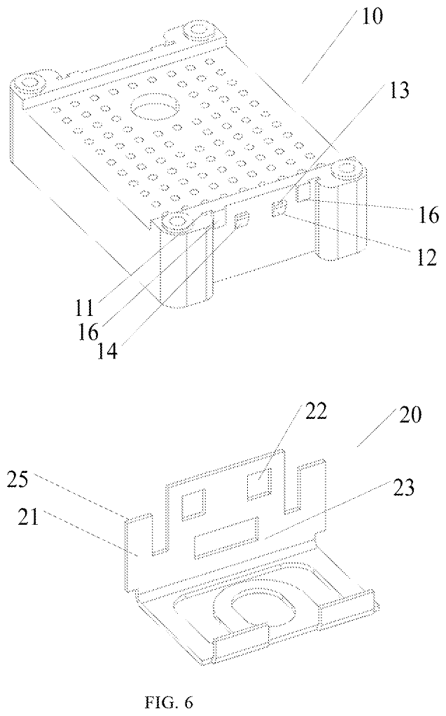

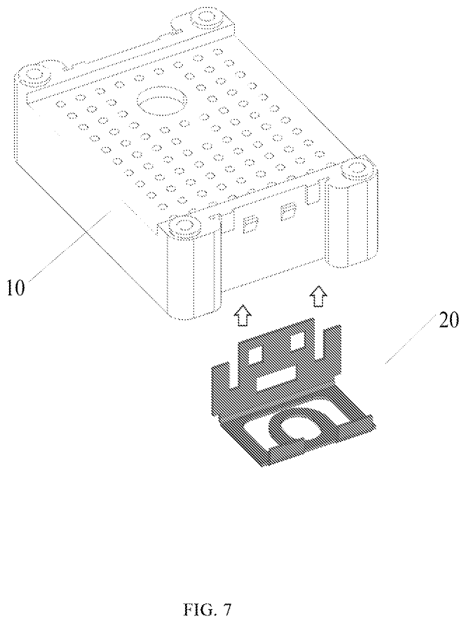

In addition, the housing 10 is provided with a first limiting portion. In the first embodiment, as shown in FIGS. 4 and 6, the first limiting portion is configured in the form of protrusions 12. The protrusions 12 and the rail corresponding portions 11 are provided on the same side wall surface of the housing 10, and the protrusions 12 are preferably located between the two rail portions 11. Each protrusion 12 has an upwardly facing non-returning surface 13 and a guiding surface 14 extending obliquely downward from the vicinity of the end of the non-returning surface 13. A transition surface may optionally be provided between the non-returning surface 13 and the guiding surface 14. That is, the guiding surface 14 terminates at its upper end in the non-returning surface 13 or the transition surface and at its lower end in the side wall of the housing 10. The guiding surface 14 may be a slope or a surface having a certain curvature.

First limiting cooperating portions, which correspond to the respective first limiting portions, are provided on the press-on element 20. In the first embodiment, the first limiting cooperating portions are windows 22 opened on the main body portion 23. Each window 22 may be rectangular in shape and sized to fit the protrusion 12. However, the window 22 may also be sized slightly larger than the protrusion 12.

As shown in FIG. 4, when the press-on element 20 is in the mounted position mounted on the housing 10, the protrusions 12 on the housing 10 could cooperate with the windows 22 on the press-on element 20 to prevent the press-on element 20 from moving downward relative to the housing 10. More specifically, when the press-on element 20 is in the mounted position, each protrusion 12 pass through the respective window 22, and the upward non-returning face 13 of the protrusion 12 could prevent the press-on element 20 from moving downward relative to the housing 10 by abutting against the downward surface of the window 22 (i.e., the upper edge of the window 22).

Further, the housing 10 and the press-on element 20 may include a second limiting portion and a second limiting cooperating portion, respectively. In the first embodiment, as shown in FIG. 4, the second limiting cooperating portion is an upper end portion 25 of each rail cooperating portion 21. The second limiting portion is a second stop surface 15 which faces downward and could cooperate with the upper end 25 of the rail cooperating portion 21. Each second stop surface 15 could be located between the corresponding rail portion 11 and protrusion 12, and could be a lower surface of a projection 16 protruding outward from an upper portion of the sidewall of the housing 10.

By designing the length of the rail cooperating portion 21 and/or the position of the second stop surface 15, the second stop surface 15 could be located just next to the upper end 25 of the rail cooperating portion 21 when the press-on element 20 is in the mounted position on the housing 10. Therefore, the second stop surface 15 could prevent the press-on element 20 from moving upward relative to the housing 10 by cooperating (abutting) the upper end portion 25 of the rail cooperating portion 21.

It could be understood that only after the press-on element 20 has reached the mounted position, the cooperation between the first limiting portion and the first limiting cooperating portion, and the cooperation between the second limiting portion and the second limiting cooperating portion, could take effect to prevent the press-on element from moving upward/downward relative to the housing.

A process of mounting the press-on element 20 to the housing 10 according to the first embodiment will now be described. After the housing 10 and the press-on element 20 are manufactured separately, the rail cooperating portions 21 of the press-on element 20 are aligned with the corresponding rail portions 11 of the housing 10 from the lower side of the housing 10 (see FIG. 7). Then, the press-on element 20 is moved in the vertically upward direction from the entry position (i.e., the position where the rail cooperating portions 21 have just entered the rail portions 11) on the lower side of the housing 10 to the mounted position shown in FIG. 4. In this process, the top of the main body portion 23 of the press-on element 20 would contact the guiding surface 14 of the protrusions 12 and move along the guiding surfaces 14, thereby slightly swinging elastically relative to the rail cooperating portions 21. Once the windows 22 reach the position where the protrusions 12 are located, the main body portion 23 elastically returns to the position coplanar with the rail cooperating portions 21, i.e., the mounted position, as the protrusions 12 pass through the windows 22.

It can be seen that the press-on element 20 could be mounted to the housing 10 by a simple pushing-in process. After reaching the mounted position, as shown in FIG. 4, the lateral movement of the press-on element 20 is restricted by the rail portions 11, and the upward and downward movements thereof are restricted by the second stop surfaces (second limiting portion) 15 and the protrusions (first limiting portion) 12, respectively, and therefore, the press-on element 20 could be reliably retained at the mounted position.

Further, the press-on element 20 in the first embodiment is detachable relative to the housing 10. When the press-on element 20 needs to be detached from the housing 10, the main body portion 23 of the press-on element 20 may be bent outward with a proper force to cause the windows 22 to be beyond the protrusions 12, and then the press-on element 20 could be pulled out from the housing 10 along the rail portions 11.

Referring to FIG. 8, similar to the structure in U.S. Pat. No. 7,477,518B2, the press-on element 20 could be further mounted on the heat sink element D by screws 44 or the like such that the heat-dissipation contact area 30 abuts against the heat sink element D tightly. During operation of the power semiconductor module 1, heat generated by the power semiconductor chip 42 is continuously dissipated to the environment via the heat conductive silicone grease and the heat sink element D. When the edge of the heat-dissipation contact area 30 tends to warp upward due to the heat generated by the semiconductor chip 42, the side walls of the housing 10 also tend to move upward along with the press-on elements 20. However, since the press-on element 20 has been fixed to the heat sink element D at this time, each press-on element 20 applies a downward counterforce to the housing 10, so that the occurrence of the above-mentioned warpage could be effectively suppressed, and in turn the problem that the heat dissipation efficiency of the power semiconductor module is hindered by the thickening of heat conductive silicone grease or even the occurrence of voids in the heat conductive silicone grease at the location where the warpage occurs could be effectively suppressed. Furthermore, since the press-on element 20 is not integrally formed with the housing 10, and the press-on element 20 may be made of a material having a certain elasticity, such as a thin metal sheet, a polymer material sheet, or the like, a flexible contact between the power semiconductor module 1 and the heat sink element D could be achieved, which is advantageous for long-term use, and the reliability of a pressing function could be ensured even in a vibrating environment. In addition, since the press-on element 20 and the housing 10 are separately manufactured, it is not necessary to precisely mold a part of the press-on element 20 to the housing 10. Therefore, the manufacture process of the power semiconductor module 1 is simple and low in cost, and could be applied not only to glue-filled plastic modules but also to plastic encapsulated modules. In addition, since the power semiconductor module 1 does not need to be baled and transported in a state where the press-on element 20 is mount, baling is easy and the transportation size is small.

As illustrated above, the first embodiment according to the present disclosure has been described with reference to the drawings. In the following description of other embodiments, components corresponding to or having the same functions as those of the components of the first embodiment will be denoted by similar reference numerals (e.g., increased (or multiplied) by hundred(s) from the reference numerals of the components of the first embodiment), and descriptions of some components, operations, effects may be omitted to avoid redundancy.

### Second Embodiment

FIGS. 9 to 11 show a housing and a press-on element of a power semiconductor module according to the second embodiment of the present disclosure. The second embodiment differs from the first embodiment in that the first limiting portion of the housing or the press-on element of the power semiconductor module is configured as a recess 112 on a housing 110, and the first limiting cooperating portion is configured as an elastic element 122 on a main body portion 123 of a press-on element 120. When the press-on element 120 is in the mounted position as shown in FIG. 9, the elastic element 122 could cooperate with the recess 112 to prevent the press-on element 120 from moving relative to the housing 110 in a direction toward the plane where the heat-dissipation contact area 30 is located (i.e., downward in FIG. 9).

Optionally, as shown in FIGS. 9 to 11, the elastic element 122 is an elastic sheet bent and/or tilted toward the housing 10. When the press-on element 120 is in the mounted position, the end of the elastic sheet 122 abuts against a surface of the recess 112 facing away from the plane where the heat-dissipation contact area 30 is located (i.e., against the lower edge of the recess 112).

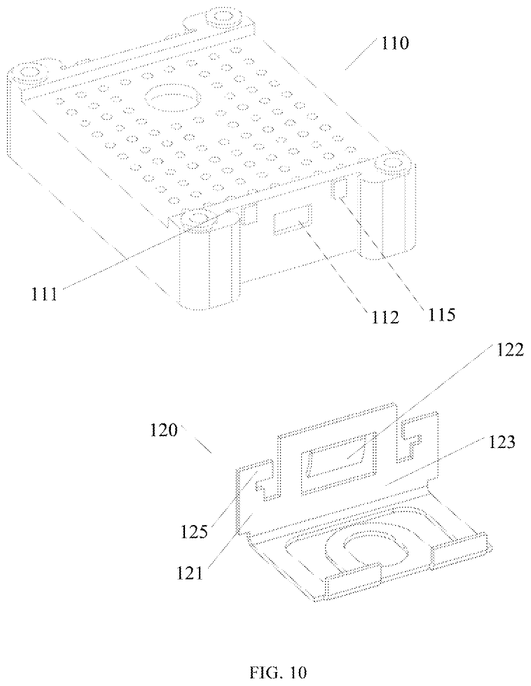

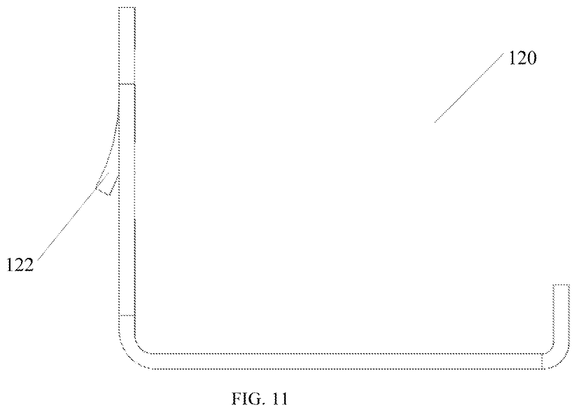

More specifically, as shown in FIG. 10, the recess 112 has a rectangular shape and is located between the two rail portions 111. The elastic element 122 is an elastic sheet extending downward from the upper edge of the window opened in the main body portion 123 of the press-on element 120. In the process of mounting the press-on element 120 to the housing 110 from bottom to top, the tip end of the elastic element 122 would first contact a portion of the sidewall of the housing below the recess 112, so that the elastic element 122 (as well as the main body portion 123) slightly swing forward (to the left in FIG. 11). Once the elastic element 122 reaches a position corresponding to the recess 112, the elastic element 122 is at least partially elastically restored, and the tip end of the elastic element 122 abuts against the lower edge of the recess 112.

Further, in the second embodiment, an upper end portion 125 of the rail cooperating portion 121 has a structure extending laterally toward the first limiting cooperating portion (i.e., the elastic element 122), and only a portion of the upper end portion 25 close to the first limiting cooperating portion serves as the second limiting cooperating portion to be cooperated with the second limiting portion. This structure enables the upper end portion 25 of the rail cooperating portion 121 to produce certain flexibility, which reduces the accuracy requirement for the positional relationship between the second limiting portion and the second limiting cooperating portion, and reduces the influence of vibration when the power semiconductor module is in the mounted state. This structure of the upper end portion 125 can also be applied to the rail cooperating portion 21 in the first embodiment, and will not be described in detail.

### Third Embodiment

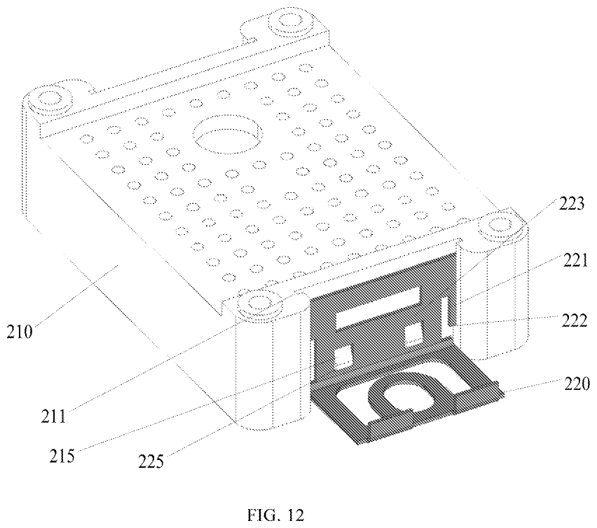

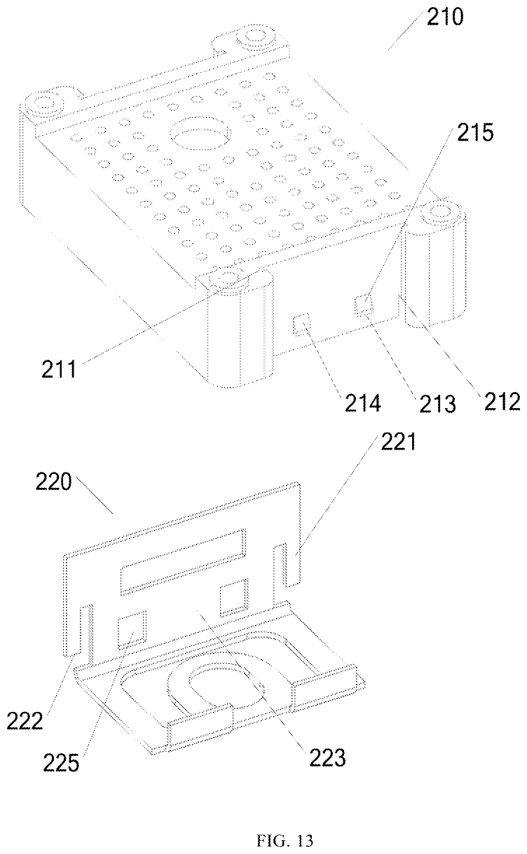

FIGS. 12 and 13 show a housing and a press-on element of a power semiconductor module according to the third embodiment of the present disclosure. The third embodiment differs from the first and second embodiments in that, a press-on element 220 of the power semiconductor module of the third embodiment is configured to be adapted to move from an entry position of a housing 210 on a side away from the heat-dissipation contact area 30 (i.e., an upper side of the housing 210 in FIG. 12) to a mounted position in a direction toward the plane where the heat-dissipation contact area 30 is located (i.e., a downward direction in FIG. 12). In addition, the first limiting portion in the third embodiment is a first stop surface 212 on the housing 210. When the press-on element 220 is in the mounted position, the first limiting cooperating portion could engage the first stop surface 212 to prevent the press-on element 220 from moving downward.

Specifically, as shown in FIG. 13, the first stop surface 212 is located in a portion of a rail portion 211 close to the heat-dissipation contact area (i.e., a lower portion of the rail portion 211), and could be a rail cut-off surface of the rail portion 211. The first limiting cooperating portion is configured as a lower end portion 222 of a rail cooperating portion 221. When the press-on element 220 is in the mounted position shown in FIG. 12, the lower end 222 of the rail cooperating portion 221 cooperates with the first stop surface 212 to prevent the press-on element 220 from moving downward.

Further, the second limiting portion in the third embodiment is configured as a protrusion 215 on the housing 210. This protrusion 215 has a structure opposite to the structure of the protrusion 12 in the first embodiment. That is, the protrusion 215 has a non-returning surface 213 facing downward and a guiding surface 214 extending obliquely upward from the vicinity of the tip end of non-returning surface 213. The guiding surface 214 is also used for guiding the main body portion 223 during the movement of the press-on element 220 from the entry position to the mounted position. The second limiting cooperating portion is configured as a window 225 on the main body portion 223. When the press-on element 220 is in the mounted position, the protrusion 215 passes through the window 225, and the non-returning surface 213 of the protrusion 215 can cooperate with the lower edge of the window 225 to prevent the press-on element 220 from moving relative to the housing 210 in a direction away from the plane where the heat-dissipation contact area 30 is located.

Optionally or additionally, the second limiting cooperating portion may be configured as a lower surface of a coupling portion between the main body portion 223 and the rail cooperating portion 221 of the press-on element 220, and the second limiting portion may be configured as an upper surface of a projection portion protruding from a position on the housing 210 corresponding to the second limiting cooperating portion.

Further, alternatively, the cooperation between the recess and the elastic element as shown in FIGS. 9 to 11 could also be applied to the third embodiment in which the press-on element 220 moves downward from the upper side of the housing 210 to the mounted position (to replace the protrusion 215 and the window 225), which will not be described further herein to avoid redundancy.

### Fourth Embodiment

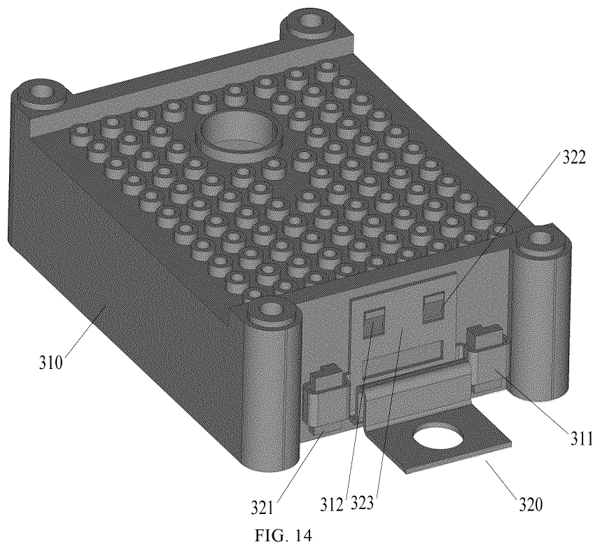

FIG. 14 shows a housing and a press-on element of a power semiconductor module according to the fourth embodiment of the present disclosure. The fourth embodiment differs from the first embodiment in that rail portions 311 in the fourth embodiment are provided on a press-on element 320, and rail cooperating portions 321 are provided on a housing 310.

Specifically, the rail cooperating portions 321 are configured to project forward from the housing 310 and then be bent to the left and right sides, respectively. The rail portions 311 are configured to laterally project from both sides of a main body portion 323 of the press-on element 320, and are bent into a C-shaped rail shape that are adapted to the cross-sectional shape of the rail cooperating portions 321. The rail cooperating portions 321 are movable in the vertical direction relative to the rail portions 311.

Further, in the fourth embodiment, the second limiting portion is not provided. In this case, the function of preventing the press-on element 320 from moving upward relative to the housing 310 may be provided by a screw or the like that fixes the press-on element 320 to the heat sink element.

### Fifth Embodiment

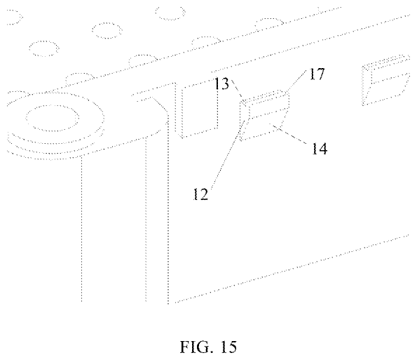

FIG. 15 is a partially enlarged view of a power semiconductor module according to the fifth embodiment of the present disclosure. The fifth embodiment differs from the first embodiment in that a self-locking structure 17 is provided on the non-returning surface 13 of each protrusion 12. The self-locking structure 17 is configured to be capable of cooperating with an upper outer side surface of the window 22 of the press-on element 20 to prevent, in cooperation with the rail portion 11, the press-on element 20 in the mounted position from moving outward in a direction away from the housing 10. The self-locking structure 17 may be a step or a rib structure provided at the end of the non-returning surface 13.

It will be understood that the self-locking structure 17 may also be applied to the protrusions 215, 312 of the third and fourth embodiments.

Although the preferred embodiments of the present disclosure have been described in detail above, the present disclosure is not limited thereto, and those skilled in the art could make various modifications and variations to the embodiments within the scope of the present disclosure.

For example, although in the above-described embodiments, the number of the press-on elements is two, and two press-on elements are respectively mounted on opposite sides of the housing, the number of the press-on elements may be one or three or more than three as needed. For example, in some applications where space is limited, one side of the power semiconductor module is a copper pin, and the other side is a press-on element. Further, as required, multiple press-on elements may be mounted on different sides of the housing, and/or multiple press-on elements may be mounted on the same side of the housing.

Although in the above-described embodiments, the number of the rail portions or the rail cooperating portions on each of the press-on elements is two, it is also possible that the number is one or three or more than three.

Although in the above-described embodiments, the numbers of the protrusions and the windows to which the protrusions correspond are two, it is also possible that the numbers are one or three or more.

Although in the above-described embodiments, the press-on element is formed in a substantially L shape, the press-on element may have other configurations. The present disclosure does not make any special limitation on the structure of the pressing member other than the portion that cooperates with the housing.

Although in the above embodiments, the press-on element is a metal element and the housing is a plastic element, other materials may be used to manufacture the press-on element or the housing as required.

Although in the above-described embodiments, the press-on element is detachable relative to the housing, it is also possible to design the press-on element in a form that is not detachable from the housing, as required. In this case, for example, a tamper-proof cover capable of shielding the main body portion of the press-on element may be provided outside the housing to avoid accessing the main body portion already in the mounted position from the outside.

Although in the above-described embodiments, the first/second limiting portion, the first/second limiting cooperating portion, the rail portion, and the rail cooperating portion are integrally formed on the housing or the press-on element, respectively, a part of the above-described elements may be manufactured separately from the housing and the press-on element, and may be mounted on the housing or the press-on element after being manufactured, as required. Furthermore, some of the above elements may be configured such that their size or position is adjustable.

Although in the above-described embodiments, the cooperation between the first limiting portion and the first limiting cooperating portion, and the cooperation between the second limiting portion and the second limiting cooperating portion are contact cooperation, more specifically, are abutting cooperation (abutting against each other), alternatively, the cooperation between the first limiting portion and the first limiting cooperating portion and/or the cooperation between the second limiting portion and the second limiting cooperating portion may be a pin cooperation or a screw cooperation.

Although in the embodiment shown in FIG. 8, the heat-dissipation contact area 30 is the bottom surface of the power semiconductor substrate 41 which is a DBC substrate, the power semiconductor substrate may be constituted by a printed circuit board, a lead frame, an AMB (active metal solder) substrate, an IMS (insulated metal substrate), or the like, and the power semiconductor substrate may be integrated with the housing 10. In addition, the heat-dissipation contact area may also be at least partially composed of a bottom surface of the power semiconductor chip, or a heat dissipation layer attached to the power semiconductor substrate, or the like, which is not limited by the present disclosure.

Although inventive subject matter has been disclosed in the context of certain preferred or illustrative embodiments and examples, it will be understood by those skilled in the art that the disclosed subject matter extends beyond the specifically disclosed embodiments to other alternative embodiments and/or uses of the disclosure, as well as obvious modifications and equivalents thereof. In addition, while a number of variations of the disclosed embodiments have been shown and described in detail, other modifications, which are within the scope of the presently disclosed subject matter, would be readily apparent to those skilled in the art based upon this disclosure. In addition, while a number of variations of the disclosed embodiments have been shown and described in detail, other modifications, which are within the scope of the presently disclosed subject matter, could be readily apparent to those skilled in the art based upon this disclosure. Accordingly, it should be understood that various features and aspects of the disclosed embodiments could be combined with or substituted for one another in order to form varying modes of the disclosed subject matter. Thus, it is intended that the scope of the inventive subject matter herein disclosed should not be limited by the particular disclosed embodiments described above but should be determined only by a fair reading of the claims.

What is claimed is:

1. A power semiconductor module, comprising:
a heat-dissipation contact area configured to thermally connect with a heat sink element,
a housing, and
a press-on element manufactured separately from the housing, wherein one of the housing and the press-on element includes a rail portion, and the other includes a rail cooperating portion, and one of the housing and the press-on element includes a first limiting portion, and the other includes a first limiting cooperating portion,
wherein the rail cooperating portion can be inserted into the rail portion and sliding in the rail portion in a direction toward or away from a plane where the heat-dissipation contact area is located, so that the press-on element is capable of moving from a separation position in which the press-on element is separated from the housing to a mounted position in which the press-on element is connected to the housing,
wherein the rail portion can cooperate with the rail cooperating portion to prevent the press-on element from moving relative to the housing in a direction parallel to the plane where the heat-dissipation contact area is located,
wherein the first limiting portion can cooperate with the first limiting cooperating portion to prevent the press-on element from moving relative to the housing in a direction toward the plane where the heat-dissipation contact area is located when the press-on element is in the mounted position, and
wherein the press-on element is configured to press the heat-dissipation contact area against the heat sink element when the press-on element is in the mounted position and the press-on element is mounted to the heat sink element.

2. The power semiconductor module according to claim 1, wherein the rail portion is located on the housing,
wherein the press-on element further includes a main body portion, and
wherein the rail cooperating portion is configured to project laterally from the main body portion and extend in a direction in which the rail portion extends.

3. The power semiconductor module according to claim 2, wherein the press-on element is configured to be adapted to move from an entry position on a side of the housing close to the heat-dissipation contact area to the mounted position in a direction away from the plane where the heat-dissipation contact area is located,
wherein the first limiting portion is configured as a protrusion on the housing, the protrusion having a non-returning surface facing away from the plane where the heat-dissipation contact area is located and a guiding surface extending obliquely from a tip end of the non-returning surface toward the heat-dissipation contact area, the guiding surface being used for guiding the main body portion during movement of the press-on element from the entry position to the mounted position, and
wherein the first limiting cooperating portion is configured as a window on the main body portion, and when the press-on element is in the mounted position, the protrusion passes through the window, and the non-returning surface of the protrusion is capable of cooperating with a surface of the window facing the plane where the heat-dissipation contact area is located to prevent the press-on element from moving relative to the housing in a direction toward the plane where the heat-dissipation contact area is located.

4. The power semiconductor module according to claim 2, wherein the press-on element is configured to be adapted to move from an entry position on a side of the housing close to the heat-dissipation contact area to the mounted position in a direction away from the plane where the heat-dissipation contact area is located,
wherein the first limiting portion is configured as a recess on the housing, and
wherein the first limiting cooperating portion is configured as an elastic element on the main body portion, and when the press-on element is in the mounted position, the elastic element is capable of cooperating with the recess to prevent the press-on element from moving relative to the housing in a direction toward the plane where the heat-dissipation contact area is located.

5. The power semiconductor module according to claim 4, wherein the elastic element is an elastic sheet that is bent and/or tilted toward the housing, and when the press-on element is in the mounted position, a tip end of the elastic sheet abuts against a surface of the recess facing away from the plane where the heat-dissipation contact area is located.

6. The power semiconductor module according to claim 2, wherein the press-on element is configured to be adapted to move from an entry position on a side of the housing away from the heat-dissipation contact area to the mounted position in a direction toward the plane where the heat-dissipation contact area is located,
wherein the first limiting portion is a first stop surface on the housing, and when the press-on element is in the mounted position, the first limiting cooperating portion is capable of cooperating with the first stop surface to prevent the press-on element from moving relative to the housing in a direction toward the plane where the heat-dissipation contact area is located.

7. The power semiconductor module according to claim 6, wherein the rail portion is located on the housing, the first stop surface is located in a portion of the rail portion close to the heat-dissipation contact area, the rail cooperating portion is located on the press-on element, and the first limiting cooperating portion is located at an end of the rail cooperating portion, and when the press-on element is in the mounted position, the first limiting cooperating portion is capable of cooperating with the first stop surface to prevent the press-on element from moving relative to the housing in a direction toward the plane where the heat-dissipation contact area is located.

8. The power semiconductor module according to claim 1, wherein the press-on element is made of a material having elasticity.

9. The power semiconductor module according to claim 1, wherein the housing and the press-on element include a second limiting portion and a second limiting cooperating portion, respectively, and when the press-on element is in the mounted position, the second limiting portion is capable of cooperating with the second limiting cooperating portion to prevent the press-on element from moving relative to the housing in a direction away from the plane where the heat-dissipation contact area is located.

10. The power semiconductor module according to claim 5, wherein the housing and the press-on element includes a second limiting portion and a second limiting cooperating portion, respectively,
wherein the second limiting portion is configured as a second stop surface facing the plane where the heat dissipation contact area is located, and the second limiting cooperating portion is located at an end of the main body portion or the rail cooperating portion, and when the press-on element is in the mounted position, the second stop surface is capable of cooperating with the second limiting cooperating portion to prevent the press-on element from moving relative to the housing in a direction away from the plane where the heat-dissipation contact area is located.

11. The power semiconductor module according to claim 6, wherein the housing and the press-on element includes a second limiting portion and a second limiting cooperating portion, respectively,
wherein the second limiting portion is configured as a protrusion on the housing, the protrusion having a non-returning surface facing away from the plane where the heat-dissipation contact area is located and a guiding surface extending obliquely away from the plane where the heat-dissipation contact area is located from a tip end of the non-returning surface, the guiding surface being used for guiding the main body portion during movement of the press-on element from the entry position to the mounted position, and
wherein the second limiting cooperating portion is configured as a window on the main body portion, and when the press-on element is in the mounted position, the protrusion passes through the window, and the non-returning surface of the protrusion is capable of cooperating with a surface of the window away from the plane where the heat-dissipation contact area is located to prevent the press-on element from moving relative to the housing in a direction away from the plane where the heat-dissipation contact area is located.

12. The power semiconductor module of claim 3, further comprising a self-locking structure that is provided on the non-returning surface, the self-locking structure is configured to be capable of cooperating with the window to prevent the press-on element in the mounted position from moving outward in a direction away from the housing.

13. The power semiconductor module of claim 11, further comprising a self-locking structure that is provided on the non-returning surface, and wherein the self-locking structure is configured to be capable of cooperating with the window to prevent the press-on element in the mounted position from moving outward in a direction away from the housing.

14. The power semiconductor module according to claim 2, wherein the rail portions are two rail portions and the rail cooperating portions are two rail cooperating portions, and spaces in the two rail portions for accommodating the corresponding rail cooperating portions are opened toward each other.

15. The power semiconductor module according to claim 1, wherein the press-on elements are at least two press-on elements, and in the mounted position, the two press-on elements are mounted on opposite sides of the housing, respectively.

16. The power semiconductor module according to claim 1, wherein the press-on element can be detachably mounted to the housing.

17. The power semiconductor module according to claim 1, wherein the power semiconductor module meets at least one of the conditions selected from the group consisting of:
the first limiting portion is integrally formed on the housing,
the first limiting cooperating portion is integrally formed on the press-on element,
the rail portion is integrally formed on the housing or the press-on element,
the rail cooperating portion is integrally formed on the housing or the press-on element,
the housing is made of plastic, and
the press-on element is made of metal.

18. A method for assembling the power semiconductor module to the heat sink element according to claim 1, wherein the method comprises the steps of:
placing the press-on element at an entry position on the housing,
sliding the rail cooperating portion in the rail portion to move the press-on element from the entry position to the mounted position, and
mounting the press-on element on the heat sink element so that the heat-dissipation contact area abuts against the heat sink element tightly.

19. The method according to claim 18, wherein before mounting the press-on element to the heat sink element, the method further comprises the step of: applying a heat conductive silicone grease on the heat-dissipation contact area and/or the surface of the heat sink element.
